(19) United States
(12) Patent Application Publication
(10) Pub. No.: US 2013/0162127 A1
(43) Pub. Date: Jun. 27, 2013

(54) ELECTRONIC DEVICE ENCLOSURE

(71) Applicant: XIU-QUAN HU, Shenzhen City (CN)

(72) Inventor: XIU-QUAN HU, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD, Shenzhen City (CN)

(21) Appl. No.: 13/610,056

(22) Filed: Sep. 11, 2012

(30) Foreign Application Priority Data
Dec. 23, 2011 (CN) 201110437573.7

(51) Int. Cl. H05K 7/14; H05K 5/02

(52) U.S. Cl. 312/223.2

(57) ABSTRACT

An electronic device enclosure includes a bracket and a tray. The bracket includes a first side plate, a second side plate substantially parallel to the first side plate, and a separated plate located between the first side plate and the second side plate. The separated plate divides the bracket into a first receiving space and a second receiving space. The first clipping hole is defined in the first side plate, and a second clipping hole is defined in the second side plate. The tray includes a clipping member which is moveable to be received in the first receiving space or the second receiving space. When the tray is received in the first receiving space, the clipping member is engaged in the first clipping hole. When the tray is received in the second receiving space, the clipping member is received in the second clipping hole.

### BACKGROUND

1. Technical Field

The present disclosure relates to electronic device enclosures, more particularly to an electronic device enclosure for receiving storage devices.

2. Description of Related Art

A plurality of storage devices are received in a bracket of a server to enhance the function of the server. The bracket comprises a first receiving space and a second receiving space. To ensure the stability of the heat dissipation of the server system, when maintaining a storage device, an empty tray is needed to receive in the bracket to replace the storage device. However, the empty tray is secured to the bracket by a plurality of screws, which is time-consuming and inconvenient. Therefore, there is room for improvement within the art.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of an electronic device enclosure in accordance with an embodiment.

FIG. 2 is an enlarged view of a circled portion II of FIG. 1.

FIG. 3 is an assembled view of a tray and a clipping member of the electronic device enclosure of FIG. 1.

FIG. 4 is an assembled view of FIG. 1, and shows the tray in a first receiving space of the electronic device enclosure.

FIG. 5 is an enlarged view of a circled portion V of FIG. 4.

FIG. 6 is similar to FIG. 4, but shows the tray in a second receiving space of the electronic device enclosure.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean at least one.

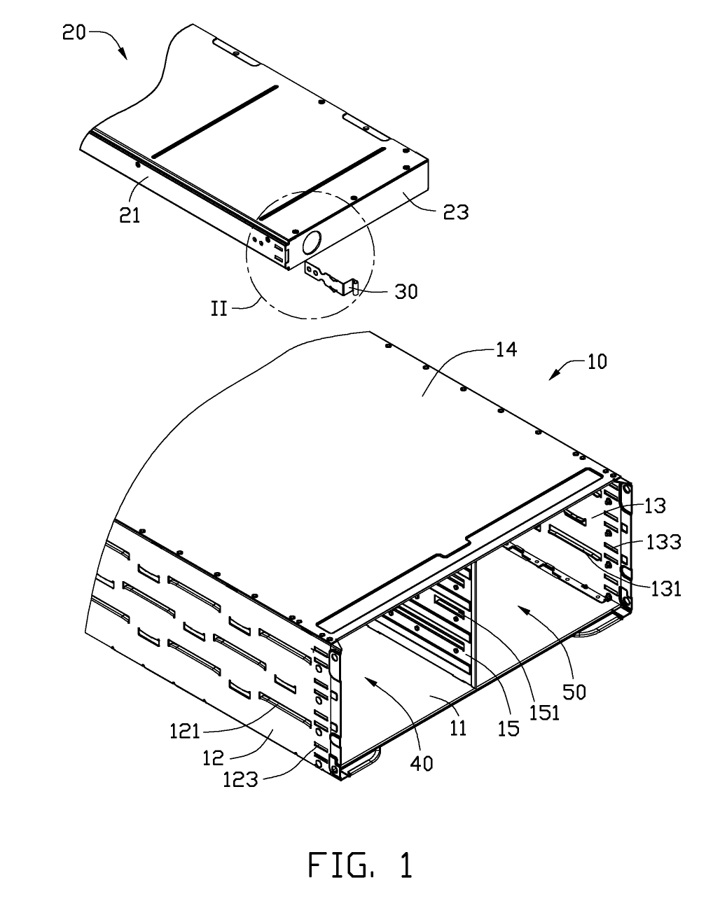

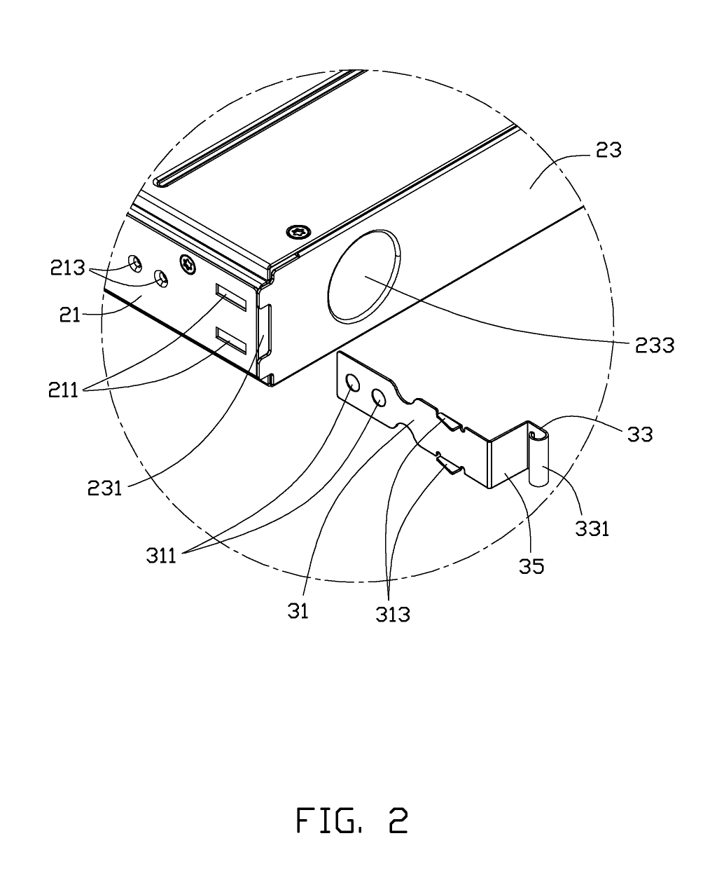

FIGS. 1 and 2 illustrate an electronic device enclosure in accordance with an embodiment. The electronic device enclosure comprises a bracket 10, a tray 20 secured to the bracket 10, and a clipping member 30 attached to the tray 20. In one embodiment, the bracket 10 is used to secure a plurality of storage devices (not shown), and a size of the tray 20 is substantially equal to that of each of the plurality of storage device.

The bracket 10 comprises a bottom plate 11, a first side plate 12, a second side plate 13, a top plate 14, and a separated plate 15 located between the first side plate 12 and the second side plate 13. In one embodiment, the first side plate 12 is substantially parallel to the second side plate 13 and perpendicular to the bottom plate 11, and the bottom plate 11 is substantially parallel to the top plate 14.

A plurality of first guiding rails 121 extend from the first side plate 12 and towards the inside of the bracket 10. A plurality of first clipping holes 123 is defined in the front portion of the first side plate 12. In one embodiment, the plurality of first clipping holes 123 are arranged at a first straight line that is substantially perpendicular to the bottom plate 11. In one embodiment, the second side plate 13 has a same configuration as the first side plate 12. A plurality of second guiding rails 131 extend from the first side plate 12 and towards the inside of the bracket 10. A plurality of second clipping holes 133 is defined in the front portion of the second side plate 13. In one embodiment, the plurality of second clipping holes 133 are arranged at a second straight line that is substantially perpendicular to the bottom plate 11. The separated plate 15 divides the bracket 10 to a first receiving space 40 and a second receiving space 50, and a plurality of separated plate guiding rails 151 extend from the separated plate 15. In one embodiment, a size of the first receiving space 40 is substantially equal to a size of the second receiving space 50.

The tray 20 comprises a side panel 21 and a front panel 23 connected to the side panel 21. In one embodiment, the side panel 21 is substantially perpendicular to the front panel 23. Two through holes 211, adjacent the front panel 23, are defined in the side panel 21. Two securing portions 213 are located on the side panel 21. An opening 231 and a receiving hole 233 are defined in the front panel 23. The opening 231 is adjacent the side panel 21. In one embodiment, the receiving hole 233 is round.

The clipping member 30 comprises a main body 31, an operating portion 33, and a connecting portion 35 connected to the main body 31 and the operating portion 33. In one embodiment, the connecting portion 35 is substantially perpendicular to the main body 31 and the operating portion 33. Two securing holes 311 are defined in the main body 31, and two clamping portions 313 extend from opposite edges of the main body 31. The clamping portions 313 are used to engage in the first clipping holes 123 or the second clipping holes 133. A curling portion 331 extends from the operating portion 33 and towards the connecting portion 35.

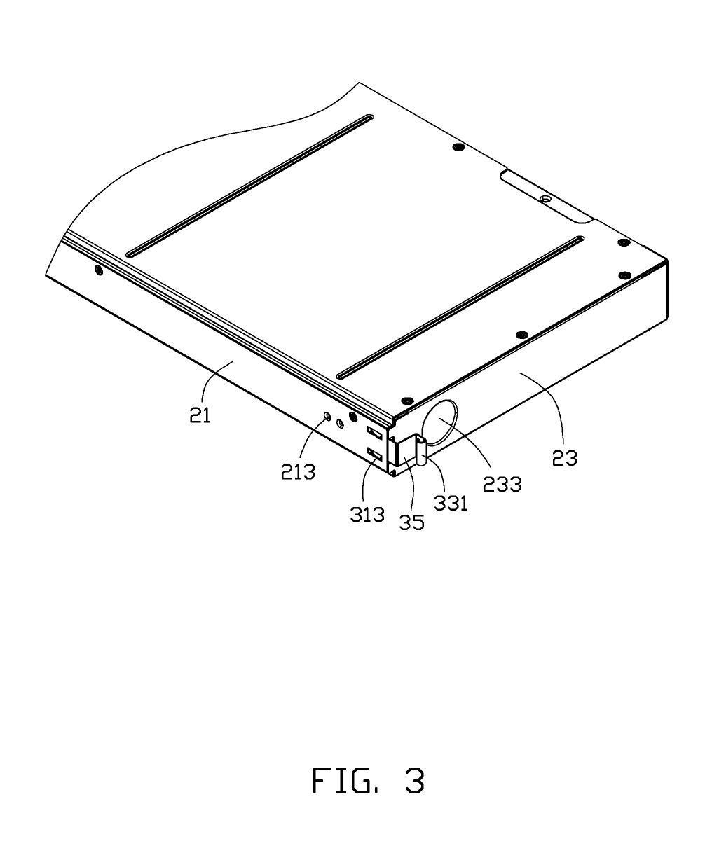

FIG. 3 illustrates an assembled view of the tray 20 and the clipping member 30 of the electronic device enclosure in accordance with an embodiment. When the clipping member 30 is secured to the tray 20, the main body 31 extends through the opening 231 to abut the inner surface of the side panel 21. The securing portions 213 is engaged in the securing holes 311, to secure the main body 31 to the side panel 21. The clamping portions 313 extend through the through holes 211 to be located on an outer surface of the side panel 21.

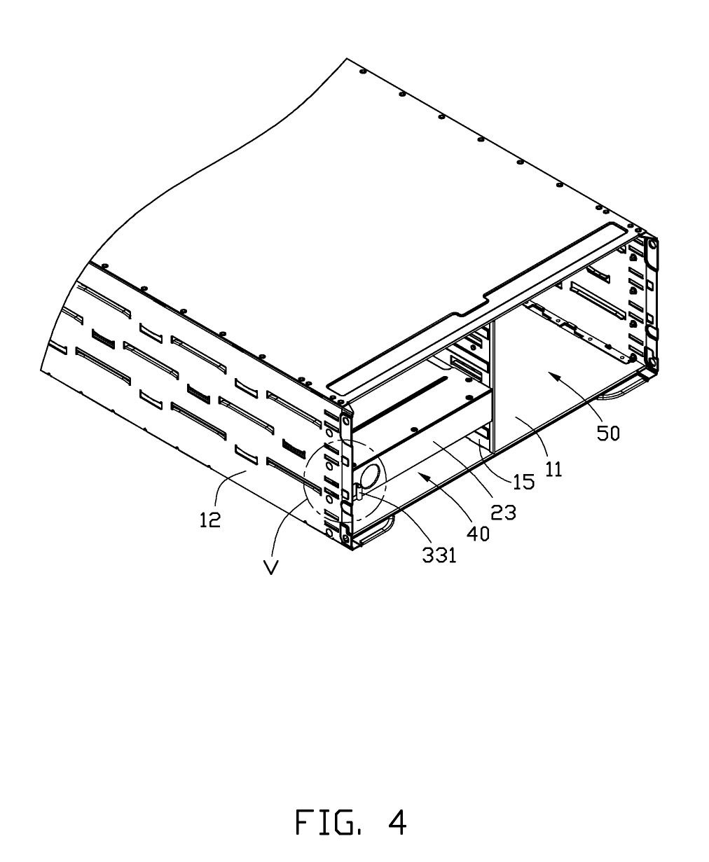

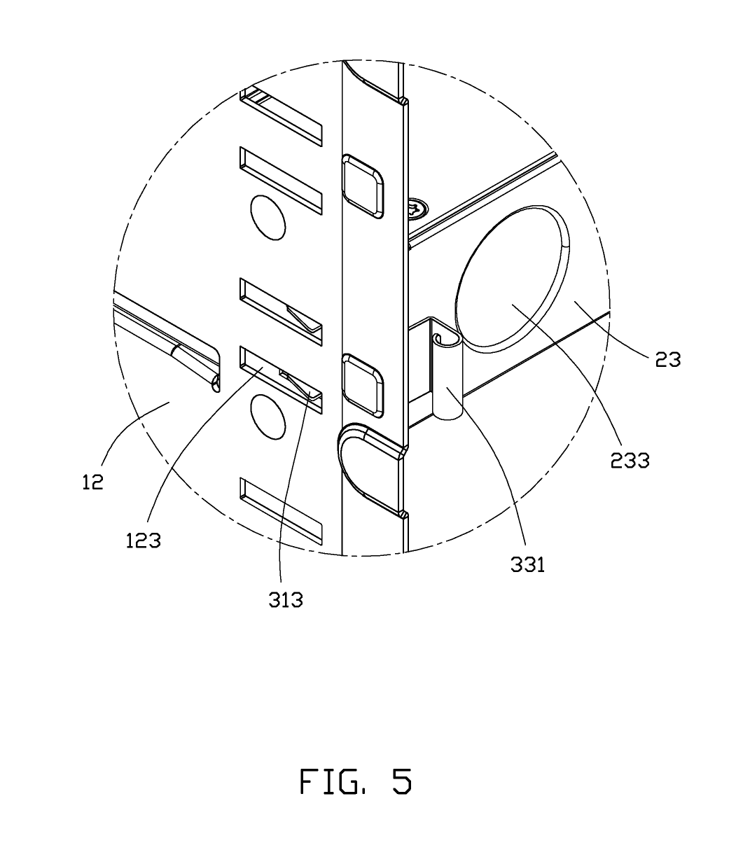

FIGS. 4-5 illustrate an assembled view of the tray 20 received in the first receiving space 40, in accordance with an embodiment. When the tray 20 is received in the first receiving space 40, the tray 20 is placed on the first guiding rails 121 and the separated plate guiding rails 151. The tray 20 is slid along the first guiding rails 121 and the separated plate guiding rails 151, until the clamping portions 313 abut the first side plate 12. The main body 31 is deformed in a direction away from the first side plate 12, and the clamping portions 313 extends through the first side plate 12. When the clamping portions 313 are aligned with the first clipping holes 123, the main body 31 is released, and the clamping portions 313 are engaged in the first clipping holes 123. Therefore, the tray 20 is secured in the first receiving space 40.

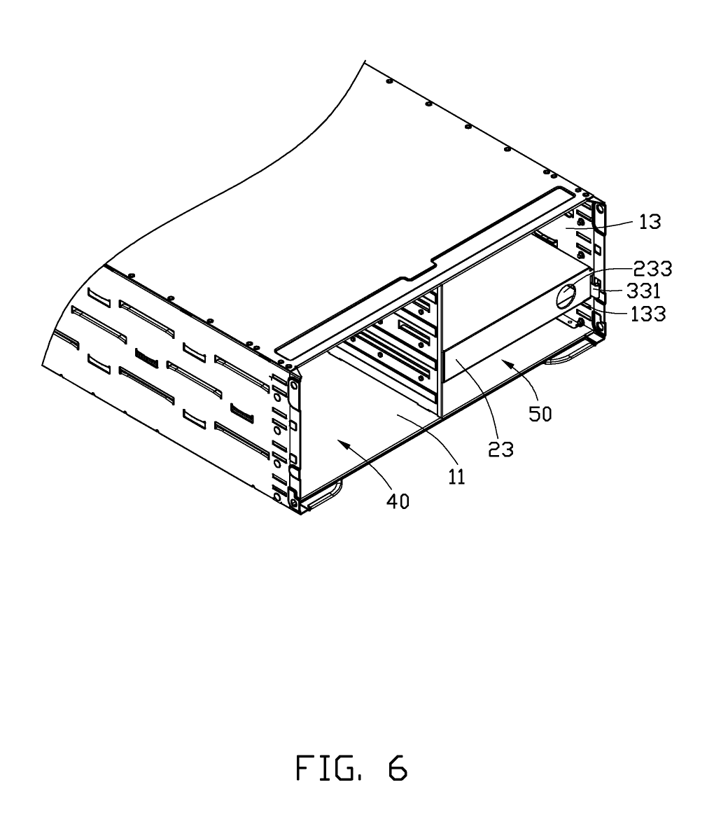

FIG. 6 illustrates an assembled view of the tray 20 received in the second receiving space 50 in accordance with an embodiment. When the tray 20 is received in the second receiving space 50, the tray 20 is rotated about 180° and placed on the second guiding rails 131 and the separated plate guiding rails 151. The tray 20 is slid along the second guiding rails 131 and the separated plate guiding rails 151, until the clamping portions 313 abut the second side plate 13. The main body 31 is deformed in a direction away from the second side plate 13, and the clamping portions 313 extends through the first side plate 12. When the clamping portions 313 are aligned with the second clipping holes 133, the main body 31 is released, and the clamping portions 313 are engaged in the second clipping holes 133. Therefore, the tray 20 is secured in the second receiving space 50.

In disassembly, the main body 31 is deformed in a direction away from the first side plate 12 or the second side plate 13, and the clamping portions 313 are disengaged from the first clipping holes 123 or the second clipping holes 133. Therefore, the tray 20 can be moved out of the first receiving space 40 or the second receiving space 50.

It is to be understood, however, that even though numerous characteristics and advantages have been set forth in the foregoing description of embodiments, together with details of the structures and functions of the embodiments, the disclosure is illustrative only and changes may be made in detail, especially in matters of shape, size, and arrangement of parts within the principles of the disclosure to the full extent indicated by the broad general meaning of the terms in which the appended claims are expressed.

What is claimed is:

1. An electronic device enclosure comprising:
a bracket comprising a first side plate, a second side plate, and a separated plate located between the first side plate and the second side plate; the second side plate being substantially parallel to the first side plate, and the separated plate dividing the bracket into a first receiving space and a second receiving space; and a first clipping hole is defined in the first side plate, and a second clipping hole is defined in the second side plate; and
a tray comprising a clipping member;
wherein the tray is received in the first receiving space or the second receiving space; and when the tray is received in the first receiving space, the clipping member is engaged in the first clipping hole, and when the tray is received in the second receiving space, the clipping member is received in the second clipping hole.

2. The electronic device enclosure of claim 1, wherein the tray comprises a side panel that is substantially parallel to the first side plate, and the clipping member is attached to the side panel.

3. The electronic device enclosure of claim 2, wherein the clipping member comprises a main body abutting the side panel, and a clamping portion extends from the main body to engage in the first clipping hole or the second clipping hole.

4. The electronic device enclosure of claim 3, wherein the side panel comprises a securing portion, and the main body defines a securing hole to receive the securing portion.

5. The electronic device enclosure of claim 3, wherein the main body abuts an inner surface of the main body, the side panel defines a through hole, and the clamping portion extends through the through hole to be located on an outer surface of the side panel.

6. The electronic device enclosure of claim 5, wherein the tray further comprises a front panel substantially perpendicular to the side panel, an opening is defined in the front panel, and the main body extends through the opening to abut the inner surface of the side panel.

7. The electronic device enclosure of claim 6, wherein the clipping member further comprises an operating portion and a connecting portion, and the connecting portion is substantially perpendicular to the operating portion and the connecting portion.

8. The electronic device enclosure of claim 7, wherein the clipping member further comprises a curling portion, and the curling portion extends from the operating portion.

9. An electronic device enclosure comprising:
a bracket comprising a first side plate, and a second side plate being substantially parallel to the first side plate;
a tray comprising a side panel, and a clipping member attached to the side panel;
wherein the tray is moveable to receive in the bracket and positioned in a first position or a second position; when the tray is positioned in the first position, the side panel abuts the first side plate, and the clipping member is engaged with the first side plate; and when the tray is positioned in the second position, the side panel abuts the second side plate, and the clipping member is engaged with the second side plate.

10. The electronic device enclosure of claim 9, wherein the bracket further comprises a separated plate located between the first side plate and the second side plate; the separated plate divides the bracket into a first receiving space and a second receiving space; and when the tray is positioned in the first position, the tray is received in the first receiving space, and when the tray is positioned in the second position, the tray is received in the second receiving space.

11. The electronic device enclosure of claim 10, wherein a first clipping hole is defined in the first side plate, a second clipping hole defined in the second side plate, when the tray is received in the first receiving space, the clipping member is engaged in the first clipping hole; and when the tray is received in the second receiving space, the clipping member is engaged in the second clipping hole.

12. The electronic device enclosure of claim 11, wherein the clipping member comprises a main body abutting the side panel, and a clamping portion extends from the main body to engage in the first clipping hole or the second clipping hole.

13. The electronic device enclosure of claim 12, wherein the side panel comprises a securing portion, and the main body defines a securing hole to receive the securing portion.

14. The electronic device enclosure of claim 12, wherein the main body abuts an inner surface of the main body, the side panel defines a through hole, and the clamping portion extends through the through hole to be located on an outer surface of the side panel.

15. The electronic device enclosure of claim 14, wherein the tray further comprises a front panel substantially perpendicular to the side panel, an opening is defined in the front panel, and the main body extends through the opening to abut the inner surface of the side panel.

16. The electronic device enclosure of claim 15, wherein the clipping member further comprises an operating portion and a connecting portion, and the connecting portion is substantially perpendicular to the operating portion and the connecting portion.

17. The electronic device enclosure of claim 16, wherein the clipping member further comprises a curling portion, and the curling portion extends from the operating portion.
